(19) United States
(12) Patent Application Publication
(10) Pub. No.: US 2018/0054927 A1
(43) Pub. Date: Feb. 22, 2018

(54) Board positioning with movable soft stop by indirect ultrasonic sensing

(71) Applicant: INTERFLUX SINGAPORE PTE LTD, Singapore (SG)

(72) Inventors: Williem Jeanne V. Van Riet, Singapore (SG); Erik Poortman, Singapore (SG)

(21) Appl. No.: 15/552,929

(22) PCT Filed: Feb. 24, 2016
(86) PCT No.: PCT/IB2016/050990

§ 371 Date: Aug. 23, 2017

Related U.S. Application Data
(60) Provisional application No. 62/120,269, filed on Feb. 24, 2015.

(51) Int. Cl. H05K 13/00; H05K 3/34; H05K 13/08; H05K 3/00

(52) U.S. Cl. CPC H05K 13/0015; H05K 13/0061; H05K 3/0008; H05K 13/08; H05K 3/3489

(57) ABSTRACT

A system, comprising: a conveyor to controllably move a substrate; a nozzle head controllably movable relative to the conveyor; an edge detector associated with the nozzle head to detect a leading edge of the substrate; and a control system coupled to the conveyor, nozzle head and edge detector to selectively and individually control both speed of the conveyor and position of the nozzle head relative to the conveyor in response to first and second leading edge detections to thereby position the substrate in a predetermined position for application of liquid flux by the nozzle head.

### FIELD

The present invention relates to positioning of printed circuit boards (PCBs or boards), or pallets holding boards, in flux machines (fluxers).

### BACKGROUND

Fluxers apply soldering flux to boards. In conventional fluxers, such as spray fluxers, boards move along a conveyor to be positioned over a spray head for fluxing.

Board positioning in conventional spray fluxers has various problems. Typically, the boards are positioned under the spray head by a hard stopper which is operated by one or more pneumatic cylinders. The hard stopper cannot be moved, so boards held in the conveyor on oversized pallets cannot be processed. Slowing the conveyor down from high speed to slow speed is jerky so components on the boards may topple. Two fixed sensors are necessary for board positioning (ie, one to detect when to slow the conveyor speed, and one to detect when the board is in position), so boards with cutouts are difficult to detect.

In addition, boards may hit the hard stopper and bounce back or knock over components. The conveyor may continue to pull a board for a while when it is already against the stopper, causing the conveyor to move under the board. This may cause some components on the board to move out of place. Pneumatic air is necessary to operate the stopper, and the hard stopper has to be physically moved to switch the direction of the conveyor. Flux residue or dirt may also influence the two sensors needed for positioning.

In this context, there is a need for solutions that address the above problems.

### SUMMARY

According to the present invention, there is provided a system, comprising:

a conveyor to controllably move a substrate;

a nozzle head controllably movable relative to the conveyor;

an edge detector associated with the nozzle head to detect a leading edge of the substrate; and

a control system coupled to the conveyor, nozzle head and edge detector to selectively and individually control both speed of the conveyor and position of the nozzle head relative to the conveyor in response to first and second leading edge detections to thereby position the substrate in a predetermined position for application of liquid flux by the nozzle head.

The control system may be configured to, in response to the first leading edge detection, slow the speed of the conveyor and advance the nozzle head ahead of the leading edge of the substrate. The substrate may be a printed circuit board or a pallet holding one or more printed circuit boards.

The control system may be further configured to, in response to the second leading edge detection, stop the conveyor and move the nozzle head to overlie the substrate.

The nozzle head may further comprise a jet nozzle or a spray nozzle.

The edge detector may be arranged in the nozzle head.

The edge detector may comprise an ultrasonic transducer underlying the jet or spray nozzle and a corner reflector offset therefrom, wherein the ultrasonic transducer and the corner reflector are arranged to project an ultrasonic beam across the conveyor that is offset ahead of the jet or spray nozzle.

The control system may comprise a programmable logic controller (PLC), a stepper motor to controllably move the conveyor, and two servo motors to controllably move the nozzle head along and across the conveyor.

The present invention also provides a method, comprising:

controllably moving a substrate by a conveyor;

controllably moving a nozzle head relative to the conveyor;

detecting a leading edge of the substrate by an edge detector associated with the nozzle head;

in response to first and second leading edge detections, selectively and individually controlling both speed of the conveyor and position of the nozzle head relative to the conveyor to thereby position the substrate in a predetermined position for application of liquid flux by the nozzle head.

The method may further comprise, in response to the first leading edge detection, slowing the speed of the conveyor and advancing the nozzle head ahead of the leading edge of the substrate.

The method may further comprise, in response to the second leading edge detection, stopping the conveyor and moving the nozzle head to overlie the substrate.

The present invention further provides a fluxer comprising the system described above, or configured to perform the method described above.

### BRIEF DESCRIPTION OF DRAWINGS

Embodiments of the invention will now be described by way of example only with reference to the accompanying drawings, in which:

FIG. 1 is a top plan view of a board positioning system for fluxers according to an embodiment of the present invention;

FIG. 2 is a perspective view of a nozzle head assembly of the system; and

FIGS. 3 to 8 are side views of the system in sequential stages of use.

### DETAILED DESCRIPTION

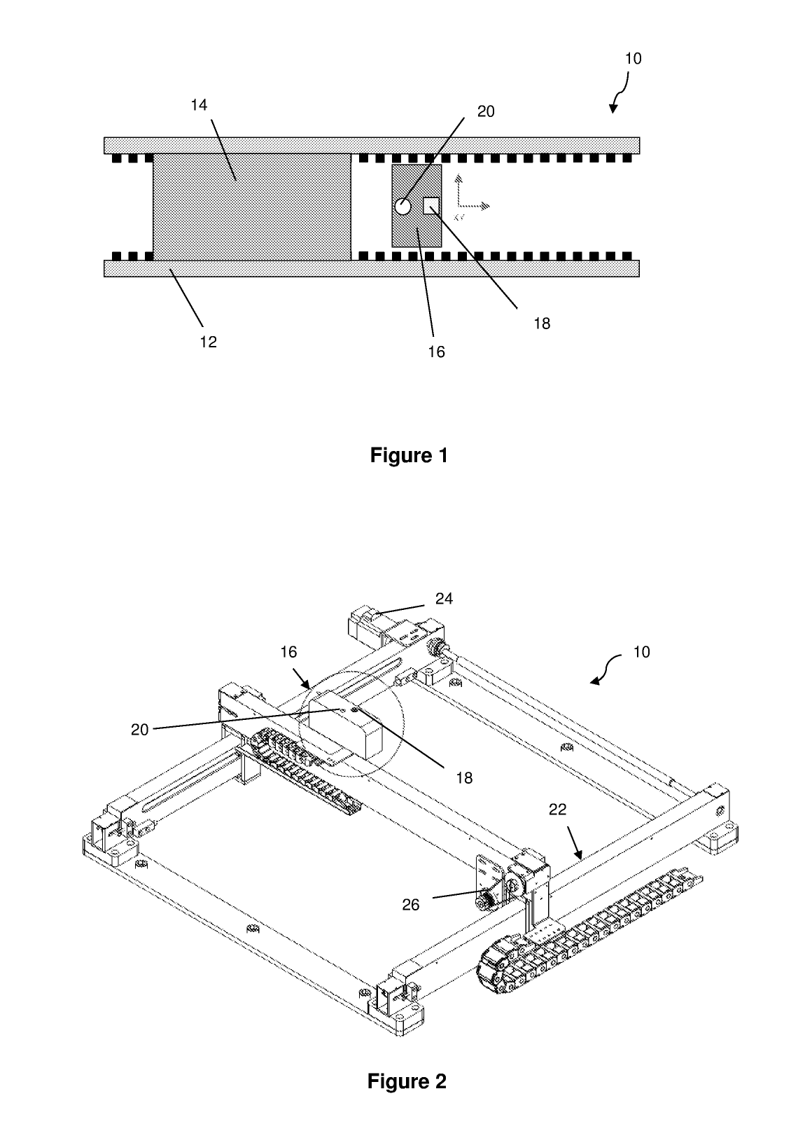

FIG. 1 illustrates a board positioning system 10 for fluxers according to an embodiment of the present invention. The system 10 may comprise a conveyor 12 to controllably move a substrate 14, and a nozzle head 16 controllably movable in X and Y directions relative to the plane of the conveyor 12. The substrate 14 may be a PCB or a pallet holding one or more PCBs. For present purposes, the substrate 14 is referred to below by way of example only as a PCB. An edge detector 18 may be associated with the nozzle head 16 to detect a leading edge of the PCB 14. For example, the edge detector 18 may be arranged on or in the nozzle head 16. The nozzle head 16 may further comprise a fluid nozzle 20, such as a jet nozzle or a spray nozzle respectively configured to generate a jet of liquid flux drops or a spray of liquid flux.

Referring to FIG. 2, the nozzle head 16 may be mounted on an X, Y gantry 22 to be controllably movable along and across the conveyor 12 by two servo motors 24, 26. The system 10 may further comprise a control system (not shown) coupled to the conveyor 12, nozzle head 16 and edge detector 18. The control system may comprise a PLC coupled to both the servo motors 24, 26 and a stepper motor to controllably move the conveyor 12. The control system may be configured, in response to first and second leading edge detections, to selectively and individually control both speed of the conveyor 12 and position of the nozzle head 16 relative to the conveyor 12 to thereby position the PCB 14 in a predetermined position for applying liquid flux by the nozzle head 16.

For example, the control system may be configured to, in response to the first leading edge detection, slow the speed of the conveyor 12 and advance the nozzle head 16 ahead of the leading edge of the PCB 14. The control system may be further configured to, in response to the second leading edge detection, stop the conveyor 12 and move the nozzle head 16 to overlie the PCB 14.

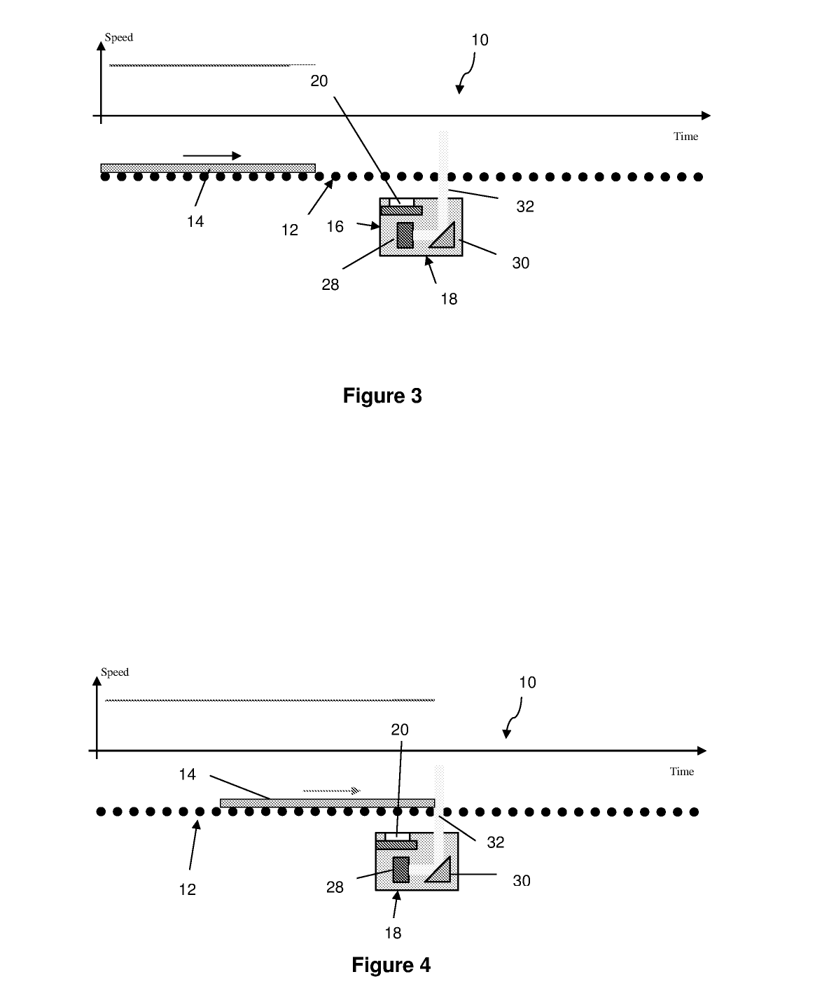

Referring to FIG. 3, the edge detector 18 may comprise an ultrasonic transducer 28 underlying the nozzle 20 and a corner reflector 30 offset ahead of the nozzle 20. The ultrasonic transducer 28 and the corner reflector 30 may be project an ultrasonic beam 32 across the conveyor 12 that is offset from the nozzle 20.

An example method of using the system 10 is illustrated in FIGS. 3 to 8. The method may generally comprise controllably moving the printed circuit board 14 by the conveyor 12, controllably moving the nozzle head 16 relative to the conveyor 12, and detecting a leading edge of the printed circuit board 14 by the edge detector 18 associated with the nozzle head 16. In response to first and second leading edge detections, the control system may selectively and individually control both speed of the conveyor 12 and position of the nozzle head 16 relative to the conveyor 12 to thereby position the PCB 14 in a predetermined position for applying a jet or spray of liquid flux by the nozzle head 16.

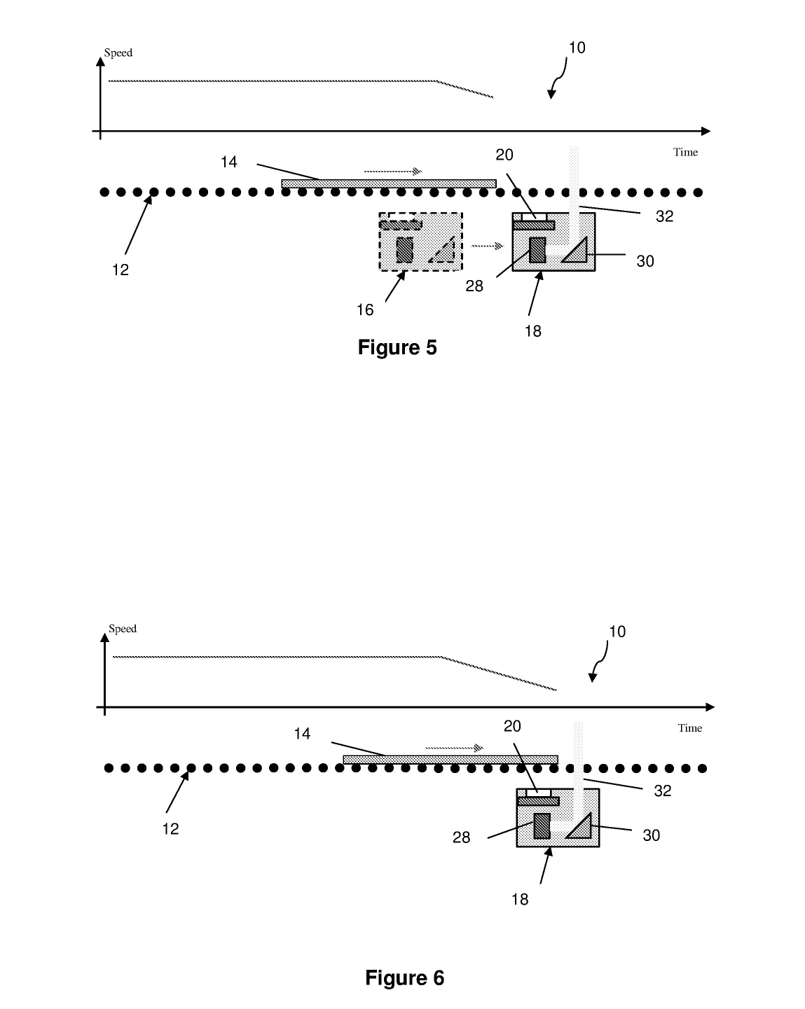

The method may further comprise, in response to the first leading edge detection, slowing the speed of the conveyor 12 and advancing the nozzle head 16 ahead of the leading edge of the PCB 14. For example, FIG. 3 illustrates the nozzle head 16 with the ultrasonic edge detector 18 in an initial waiting position, or first edge detection position, for the board 14. At this stage the board may travel at high speed, for example, around 400 mm per second. In FIG. 4, the PCB 14 moves along the conveyor 12 and reaches the ultrasonic sensor beam 24 resulting in a first edge detection. In response to the first edge detection, the PCB 14 is slowed down by reducing the speed of the conveyor 12. The nozzle head 16 then advances with the edge detector 18 along the conveyor 12 at high speed, for example around 1500 mm per second, to a subsequent waiting position, or second edge detection position, ahead of the PCB 14, as illustrated in FIG. 5.

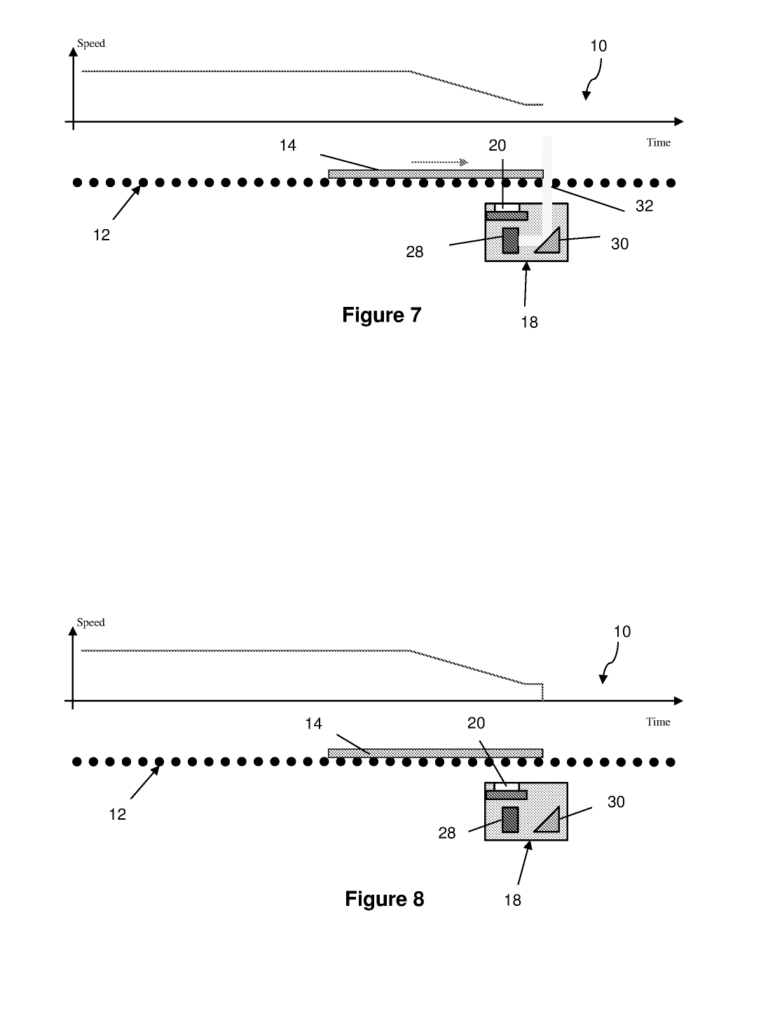

The method may further comprise, in response to the second leading edge detection, stopping the conveyor 12 and moving the nozzle head 16 to overlie the PCB 14. For example, FIG. 6 illustrates the nozzle head 16 with the edge detector 18 in the second edge detection position. The speed of the conveyor 12 is then slowed down further to a positioning speed, for example, around 10 mm per second. As illustrated in FIG. 7, the PCB 14 moves toward the ultrasonic beam 24 of the edge detector 18 at the positioning speed. When the PCB 14 reaches the ultrasonic beam 24 as illustrated in FIG. 8, the PCB 14 stops in a flux application position overlying the nozzle 20 of the nozzle head 16. The conveyor 12 clamps the PCB 14 while the fluxing cycle starts. The PCB 14 does not move during the whole fluxing cycle. When the fluxing cycle is complete, the fluxed PCB 14 is advanced away from the nozzle head 16 by the conveyor 12, and the board positioning sequence described above is repeated for the next unfluxed PCB 14.

Embodiments of the present invention provide a board positioning system and method that may be usefully implemented in a computer-controlled fluxer, such as a spray or jet fluxer. Embodiments of the invention enable positioning of PCBs or pallets with a moveable soft stop provided by an ultrasonic sensor when the PCBs or pallets are entering the machine at high speed. The nozzle head (or nozzle body assembly) waits at a pre-calculated position when the PCB or pallet enters the machine at high speed. A first detection by the ultrasonic sensor will then take place. The conveyor will ramp down to a slow speed while the nozzle assembly moves to the board positioning location at high speed. There a second detection by the same ultrasonic sensor will take place, positioning the board accurately before the cycle will start. Embodiments of the invention provide very accurate positioning because it uses an ultrasonic sensor to perform a two-step, high speed detection. Because the ultrasonic sensor is mounted on the nozzle assembly, no hard stopper is necessary. So embodiments of the invention are able to accurately position oversized pallets. They are also able to slow down the conveyor by ramping down the speed, not disturbing the components. Since only one sensor is used, which is moveable, detecting boards with cutouts is also possible.

The board will not hit any stopper, so components cannot move by hitting it, nor will the conveyor push or pull the board. No pneumatic air is necessary so the direction of the machine can be changed without any physical change to the machine. Furthermore, since the sensor is ultrasonic it will not be influenced by flux residue or dirt. Additionally, the flux cannot leak on the sensor due to the offset, angled setup of the sensor.

For the purpose of this specification, the word “comprising” means “including but not limited to”, and the word “comprises” has a corresponding meaning.

The above embodiments have been described by way of example only and modifications are possible within the scope of the claims that follow.

1. A system, comprising:
a conveyor to controllably move a substrate;
a nozzle head controllably movable relative to the conveyor;
an edge detector associated with the nozzle head to detect a leading edge of the substrate; and
a control system coupled to the conveyor, nozzle head and edge detector to selectively and individually control both speed of the conveyor and position of the nozzle head relative to the conveyor in response to first and second leading edge detections to thereby position the substrate in a predetermined position for application of liquid flux by the nozzle head.

2. The system of claim 1, wherein the control system is configured to, in response to the first leading edge detection, slow the speed of the conveyor and advance the nozzle head ahead of the leading edge of the substrate.

3. The system of claim 2, wherein the control system is further configured to, in response to the second leading edge detection, stop the conveyor and move the nozzle head to overlie the substrate.

4. The system of claim 1, wherein the nozzle head further comprises a jet nozzle or a spray nozzle.

5. The system of claim 1, wherein the edge detector is arranged in the nozzle head.

6. The system of claim 5, wherein the edge detector comprises an ultrasonic transducer underlying the jet or spray nozzle and a corner reflector offset therefrom, wherein the ultrasonic transducer and the corner reflector are arranged to project an ultrasonic beam across the conveyor that is offset ahead of the jet or spray nozzle.

7. The system of claim 1, wherein the control system comprises a programmable logic controller (PLC), a stepper motor to controllably move the conveyor, and two servo motors to controllably move the nozzle head along and across the conveyor.

8. The system of claim 1, wherein the substrate is a printed circuit board or a pallet holding one or more printed circuit boards.

9. A method, comprising:
controllably moving a substrate by a conveyor;
controllably moving a nozzle head relative to the conveyor;
detecting a leading edge of the substrate by an edge detector associated with the nozzle head;
in response to first and second leading edge detections, selectively and individually controlling both speed of the conveyor and position of the nozzle head relative to the conveyor to thereby position the substrate in a predetermined position for application of liquid flux by the nozzle head.

10. The method of claim 9, further comprising, in response to the first leading edge detection, slowing the speed of the conveyor and advancing the nozzle head ahead of the leading edge of the substrate.

11. The method of claim 10, further comprising, in response to the second leading edge detection, stopping the conveyor and moving the nozzle head to overlie the substrate.

12. The method of claim 9, wherein the substrate is a printed circuit board or a pallet holding one or more printed circuit boards.

13. A fluxer comprising the system of claim 1.

14. A fluxer configured to perform the method of claim 9.
